(19) United States
(12) Patent Application Publication
(10) Pub. No.: US 2010/0084765 A1
(43) Pub. Date: Apr. 8, 2010

(54) Semiconductor package having bump ball

(75) Inventors: Chang Bae Lee, Gyunggi-do (KR); Sang Hun Park, Gyunggi-do (KR); Jin Su Kim, Gyunggi-do (KR); Jong Woo Choi, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/320,122

(22) Filed: Jan. 16, 2009

(30) Foreign Application Priority Data
Oct. 2, 2008 (KR) 10-2008-0097302

(51) Int. Cl. H01L 23/48; H01L 23/498

(52) U.S. Cl. 257/738; 257/E23.069

(57) ABSTRACT

Disclosed is a semiconductor package having a bump ball as an external connection terminal, the bump ball including a core layer containing copper, a copper alloy, aluminum, an aluminum alloy or a combination thereof and a shell layer surrounding the core layer and containing tin, a tin alloy or a combination thereof.

### CROSS REFERENCE TO RELATED APPLICATION

This application claims the benefit of Korean Patent Application No. 10-2008-0097302, filed Oct. 2, 2008, entitled “Semiconductor package having bump ball”, which is hereby incorporated by reference in its entirety into this application.

### BACKGROUND OF THE INVENTION

1. Field of the Invention

The present invention relates to a semiconductor package having a bump ball. More particularly, the present invention relates to a semiconductor package having a bump ball which includes a core layer containing copper, a copper alloy, aluminum, an aluminum alloy or a combination thereof and a shell layer surrounding the core layer and containing tin, a tin alloy or a combination thereof.

2. Description of the Related Art

As the demand for reduction in the size and thickness of electronic products and components increases day by day, thorough research and development into a wafer level package is recently being conducted, and application products thereof successively appear in the markets. The major technical issue in realizing a module using the wafer level package technique is to minimize the generation of stress and strain due to difference in a coefficient of thermal expansion (CTE) and in stiffness between a wafer (die) and a printed circuit board (PCB).

Solder bumps for package interconnection are formed on the surface of a wafer using a solder ball and a solder paste through printing/plating/ball attaching, and the wafer is bonded to the PCB by means of the bumps in order to realize a package module. As such, while part or all of the solder bumps of the bonding portion are melted and then solidified, they are fused and diffused with the surface of a UBM (Under Bump Metallurgy) layer formed on each die of the wafer and the surface of the connection pad of the PCB, thus forming an intermetallic compound. The intermetallic compound thus formed is intensively subjected to stress due to volume shrinkage and CTE mismatch upon formation thereof and thus consequently gets broken.

Below, with reference to FIG. 1, attachment of a conventional bump ball to a connection pad of a semiconductor substrate is described.

As shown in FIG. 1, in order to reduce stress and improve a bump stand-off height, the conventional bump ball 10 includes a polymer core 11, a nickel layer 12 surrounding the polymer core 11, a copper layer 13 surrounding the nickel layer 12, and a solder layer 14 surrounding the copper layer 13. The solder layer 14 of the bump ball 10 is attached to the semiconductor substrate 20, particularly, the connection pad 21 of the semiconductor substrate 20. The portion of the semiconductor substrate 20 other than the portion to which the bump ball 10 is bonded is protected with a protective layer 22.

However, such a bump ball 10 provides limited improvement in the reliability of a solder joint. In the bump ball 10, because the solder layer 14 is directly formed on the copper layer 13, the copper layer 13 is interconnected with the solder layer 14 through fusion and diffusion due to heat applied to the bump ball 10 in the course of attaching the bump ball 10 to the semiconductor substrate 20, thus forming a double intermetallic compound layer, for example, a Cu₆Sn₅/Cu₃Sn layer, at the bonding interface between the copper layer and the solder layer.

The double intermetallic compound layer thus formed may easily become brittle and thus act as a cause of cracking the attached bump ball 10. Also, in the bonding process, the copper layer 13 is fused and diffused to the solder layer 14 due to heat applied to the bump ball 10 in the course of attaching the bump ball 10 to the semiconductor substrate 20. Further, the fused and diffused copper is moved through a diffusion action between the bump ball 10 and the connection pad 21, more specifically, to the bonding interface between the bump ball 10 and the connection pad 21 of the semiconductor substrate 20, thus forming a double intermetallic compound layer 15 at the bonding interface therebetween, undesirably weakening the force of adhesion between the bump ball 10 and the connection pad 21. The case where the connection pad 21 is formed of copper (Cu) facilitates the formation of the double intermetallic compound layer due to copper (Cu) moved through diffusion to the bonding interface. Below, with reference to FIG. 2 showing the enlarged view of the portion A of FIG. 1, an aspect of the formed double intermetallic compound layer is described.

As shown in FIG. 2, the double intermetallic compound layer 15 is formed at the bonding interface between the copper layer 13 and the solder layer 14 in the bump ball 10, and the double intermetallic compound layer 15 is also formed at the bonding interface between the solder layer 14 and the connection pad 21 of the semiconductor substrate 20 through diffusion. Such a double intermetallic compound layer 15 formed due to the diffusion of copper, easily turns brittle, undesirably deteriorating the reliability of the solder joint between the bump ball and the semiconductor substrate.

In the case of the polymer core according to the conventional technique, the material and the properties of the material used in the polymer core are different from the metal and its properties typically used in the bump ball, making it difficult to manufacture and apply the polymer core.

Therefore, there is an urgent requirement to develop a bump ball which includes a metallic core and is capable of preventing the formation of the aforementioned double intermetallic compound layer and which is capable of forming a stable interface in the form of a single layer.

### SUMMARY OF THE INVENTION

Leading to the present invention, thorough and extensive research aiming to solve the problems encountered in the related art, resulted in the finding that the core layer of a bump ball may be formed of a specific metal or metal alloy, thus preventing the formation of a double intermetallic compound layer, thereby reducing stress intensively applied to the bonding portion and reducing the generation of cracks.

Accordingly, the present invention provides a semiconductor package having a bump ball, which can prevent the formation of a double intermetallic compound layer which brings about intensive application of stress upon formation of a bump and interconnection of a package.

In addition, the present invention provides a semiconductor package having a bump ball, which can exhibit superior package bonding reliability even when only a solder component is applied to a core layer made of a specific metal.

In addition, the present invention provides a semiconductor package having a bump ball, which can exhibit superior thermal impact and drop properties.

According to a preferred embodiment of the present invention, there is provided a semiconductor package having a bump ball as an external connection terminal, the bump ball including a core layer containing copper, a copper alloy, aluminum, an aluminum alloy or a combination thereof, and a shell layer surrounding the core layer and containing tin, a tin alloy or a combination thereof.

In the semiconductor package having a bump ball, the core layer may be formed of a copper alloy. Also, the core layer may include a first layer made of copper and a second layer surrounding the first layer and containing a copper alloy.

The copper alloy may be CuZn, CuCo, CuNi or a combination thereof.

The core layer may further include Zn, Co, Ni or a combination thereof.

As a first example, the core layer may be formed of CuZn, the composition of CuZn consisting of 40˜99.9 wt % of Cu and 0.1˜60 wt % of Zn.

As a second example, the core layer may be formed of CuCo, the composition of CuCo consisting of 0.1˜99.9 wt % of Cu and 0.1˜99.9 wt % of Co.

As a third example, the core layer may be formed of CuNi, the composition of CuNi consisting of 0.1˜99.9 wt % of Cu and 0.1˜99.9 wt % of Ni.

In addition, as a first example, the second layer may be formed of CuZn, the composition of CuZn consisting of 0.1˜99.9 wt % of Cu and 0.1˜99.9 wt % of Zn.

As a second example, the second layer may be formed of CuCo, the composition of CuCo consisting of 0.1˜99.9 wt % of Cu and 0.1˜99.9 wt % of Co.

As a third example, the second layer may be formed of CuNi, the composition of CuNi consisting of 0.1˜99.9 wt % of Cu and 0.1˜99.9 wt % of Ni.

In the case where the core layer is formed of aluminum or an aluminum alloy, the bump ball may further include an intermediate layer containing nickel between the core layer and the shell layer.

The aluminum alloy may be AlCu, AlZn, AlSi, AlMn, AlMg or a combination thereof.

### BRIEF DESCRIPTION OF THE DRAWINGS

FIG. 1 is a schematic cross-sectional view showing a semiconductor package having a bump ball according to a conventional technique;

FIG. 2 is an enlarged view of the portion A of FIG. 1;

FIG. 3 is a schematic cross-sectional view showing a semiconductor package having a bump ball according to a preferred embodiment of the present invention;

FIG. 4 is a schematic cross-sectional view showing a semiconductor package having a bump ball according to another preferred embodiment of the present invention; and

FIG. 5 is a schematic cross-sectional view showing a semiconductor package having a bump ball according to a further preferred embodiment of the present invention.

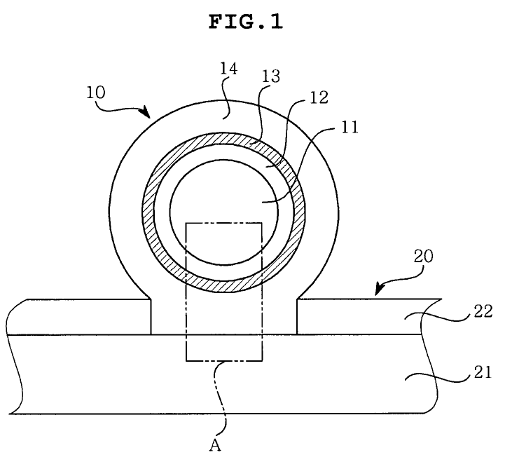

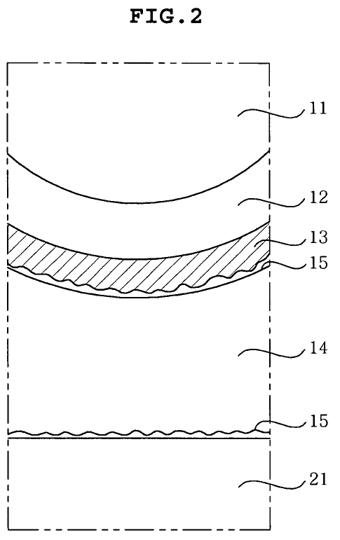

### DESCRIPTION OF THE PREFERRED EMBODIMENTS

The features and advantages of the present invention will be more clearly understood from the following detailed description taken in conjunction with the accompanying drawings.

Further, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to describe best the method he or she knows for carrying out the invention.

Throughout the drawings, the same reference numerals refer to the same or similar elements, and redundant descriptions are omitted. In order to make the characteristics of the invention clear and for the convenience of description, a detailed description pertaining to the other known techniques may be omitted. In the description, the terms “first”, “second” and so on are used to distinguish one element from another element, but are not to be construed to limit the elements.

Hereinafter, a more detailed description will be given of the present invention, with reference to the accompanying drawings.

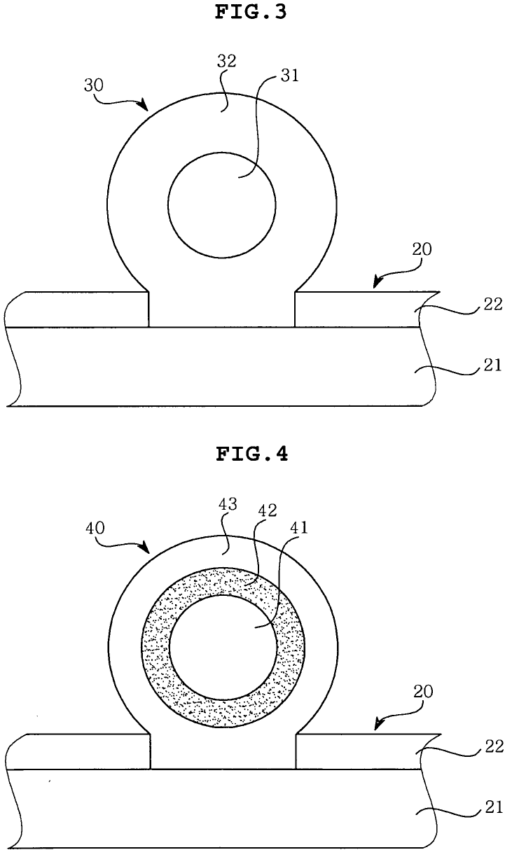

FIGS. 3 to 5 are schematic cross-sectional views showing the semiconductor package having a bump ball according to three preferred embodiments of the present invention.

In the above drawings, the other detailed elements of the semiconductor substrate, with the exception of the characteristic elements of the corresponding embodiment, are omitted, and the corresponding elements are schematically depicted. The bump ball structure according to the present invention may be applied without limitation to any semiconductor package structure known in the art, as so understood by those skilled in the art.

Below, a semiconductor package having a bump ball according to a preferred embodiment of the present invention is described with reference to FIG. 3.

The semiconductor package having a bump ball according to the preferred embodiment of the present invention has, as an external connection terminal on the connection pad 21 of a semiconductor substrate 20 such as a wafer, a bump ball 30 which includes a core layer 31 containing copper, a copper alloy, aluminum or an aluminum alloy and a shell layer 32 surrounding the core layer 31, wherein the shell layer contains tin or a tin alloy. The shell layer 32 is not particularly limited, and may be formed through a coating process known in the art, for example, electroplating, electroless plating, dipping, etc.

The core layer 31 may be formed of a copper alloy. Specifically, the core layer 31 may be formed of any one copper alloy selected from among CuZn, CuCo, CuNi and combinations thereof.

As a first example, the core layer 31 is formed of CuZn, the composition of CuZn consisting of 40˜99.9 wt % of Cu and 0.1˜60 wt % of Zn in order to prevent the formation of a double intermetallic compound layer and realize desired bonding reliability.

As a second example, the core layer 31 is formed of CuCo, the composition of CuCo consisting of 0.1˜99.9 wt % of Cu and 0.1˜99.9 wt % of Co in order to prevent the formation of a double intermetallic compound layer and realize desired bonding reliability.

As a third example, the core layer 31 is formed of CuNi, the composition of CuNi consisting of 0.1˜99.9 wt % of Cu and 0.1˜99.9 wt % of Ni in order to prevent the formation of a double intermetallic compound layer and realize desired bonding reliability.

The core layer 31 may further include any one or a combination of two or more selected from among Zn, Co, and Ni.

The semiconductor package having a bump ball according to the above embodiment of the present invention can prevent the formation of a double intermetallic compound layer (Cu₆Sn₅/Cu₃Sn) which affects semiconductor package bonding reliability even when a shell layer composed of a tin-based solder component is directly applied without the use of a typical diffusion barrier layer, for example, a nickel-containing layer, which prevents the formation of an intermetallic compound.

Specifically, although the formation and growth of the double intermetallic compound layer negatively affect the package bonding reliability attributable to volume shrinkage, thermal mismatch, and Kirkendall voids upon formation of two phases, according to the present embodiment, the formation of such a double intermetallic compound layer can be prevented, thus obtaining superior bonding reliability.

In the case where the copper alloy such as CuZn, CuCo or CuNi is used as the core layer, the intermetallic compounds depending on the respective compositions are illustrated as follows.

CuZn: Cu₆Sn₅, CuZn (Cu₅Zn₈)

CuCo: Cu₆Sn₅, CoSn₂, (Cu,Co)₆Sn₅

CuNi: (Cu,Ni)₆Sn₅, (Cu,Ni)₃Sn₄

In the present invention, the double intermetallic compound layer such as Cu₆Sn₅/Cu₃Sn is not formed, and the formation of Kirkendall voids may be prevented.

Also, in the case where an element such as Zn, Co or Ni is added, the formation of the intermetallic compound between the core layer 31 and the shell layer 32 can be prevented, thus obtaining desired bonding reliability even without the additional use of a diffusion barrier layer.

Below, a semiconductor package having a bump ball according to another preferred embodiment of the present invention is described with reference to FIG. 4.

The semiconductor package having a bump ball according to another preferred embodiment of the present invention has, as an external connection terminal on the connection pad 21 of a semiconductor substrate 20, a bump ball 40 which includes a core layer composed of a first layer 41 made of copper and a second layer 42 surrounding the first layer 41 and containing a copper alloy, and a shell layer 43 surrounding the core layer and containing tin or a tin alloy. The second layer 42 and the shell layer 43 are not particularly limited, and may be formed through a coating process known in the art, for example, electroplating, electroless plating, dipping, etc.

The second layer 42 may be formed of any one copper alloy selected from among CuZn, CuCo, CuNi and combinations thereof.

As a first example, the second layer 42 is formed of CuZn, the composition of CuZn consisting of 0.1˜99.9 wt % of Cu and 0.1˜99.9 wt % of Zn in order to prevent the formation of a double intermetallic compound layer and realize desired bonding reliability.

As a second example, the second layer 42 is formed of CuCo, the composition of CuCo consisting of 0.1˜99.9 wt % of Cu and 0.1˜99.9 wt % of Co in order to prevent the formation of a double intermetallic compound layer and realize desired bonding reliability.

As a third example, the second layer 42 is formed of CuNi, the composition of CuNi consisting of 0.1˜99.9 wt % of Cu and 0.1˜99.9 wt % of Ni in order to prevent the formation of a double intermetallic compound layer and realize desired bonding reliability.

The second layer 42 may further include any one or a combination of two or more selected from among Zn, Co, and Ni.

The semiconductor package having a bump ball according to the above embodiment of the present invention can prevent the formation of a double intermetallic compound layer (Cu₆Sn₅/Cu₃Sn) which affects semiconductor package bonding reliability, and also, can suppress the formation of Kirkendall voids.

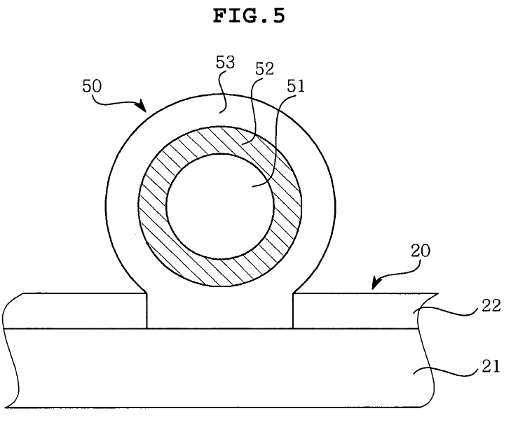

Below, a semiconductor package having a bump ball according to a further preferred embodiment of the present invention is described with reference to FIG. 5.

The semiconductor package having a bump ball according to the further preferred embodiment of the present invention has, as an external connection terminal on the connection pad 21 of a semiconductor substrate 20, a bump ball 50 which includes a core layer 51 made of aluminum or an aluminum alloy, an intermediate layer 52 surrounding the core layer 51 and containing nickel, and a shell layer 53 surrounding the intermediate layer 52 and containing tin or a tin alloy. The intermediate layer 52 may function as a typical diffusion barrier layer. The intermediate layer 52 and the shell layer 53 are not particularly limited, and may be formed through a coating process known in the art, for example, electroplating, electroless plating, dipping, etc.

The aluminum alloy may include any one selected from among AlCu, AlZn, AlSi, AlMn, AlMg and combinations thereof.

The semiconductor package having a bump ball according to the above embodiment of the present invention can prevent the formation of the double intermetallic compound layer affecting semiconductor package bonding reliability, and also, can suppress the formation of Kirkendall voids.

As well, in the case where the aluminum-based core is used as the core layer (core ball), it may result in stiffness of a predetermined level or more, thus making it possible to apply it to a semiconductor package structure requiring a strength and/or a bump stand-off height of at least a specific level.

In this way, according to the present invention, when not the polymer core but the core layer containing copper, a copper alloy, aluminum or an aluminum alloy is introduced to the bump ball of the semiconductor package, the type and growth rate of the intermetallic compound, which adversely affects the bonding reliability after the bonding process (after the acceleration test), can be controlled.

As described hereinbefore, the present invention provides a semiconductor package having a bump ball. In the semiconductor package having a bump ball according to the present invention, even when a tin-based solder component is directly applied to a core layer without the use of a typical diffusion barrier layer, the formation of a double intermetallic compound layer and Kirkendall voids adversely affecting package bonding reliability can be prevented.

In addition, the formation and growth of the intermetallic compound can be controlled, thus improving thermal impact and drop properties.

Although the preferred embodiments of the present invention regarding the semiconductor package having a bump ball have been disclosed for illustrative purposes, those skilled in the art will appreciate that various modifications, additions and substitutions are possible within the technical scope of the invention.

What is claimed is:

1. A semiconductor package having a bump ball as an external connection terminal, the bump ball comprising:
a core layer containing copper, a copper alloy, aluminum, an aluminum alloy or a combination thereof; and
a shell layer surrounding the core layer and containing tin, a tin alloy or a combination thereof.

2. The semiconductor package as set forth in claim 1, wherein the core layer comprises a copper alloy.

3. The semiconductor package as set forth in claim 1, wherein the core layer comprises a first layer made of copper and a second layer surrounding the first layer and containing a copper alloy.

4. The semiconductor package as set forth in claim 1, wherein the copper alloy is CuZn, CuCo, CuNi or a combination thereof.

5. The semiconductor package as set forth in claim 1, wherein the core layer further comprises Zn, Co, Ni or a combination thereof.

6. The semiconductor package as set forth in claim 1, wherein the core layer comprises CuZn, a composition of the CuZn consisting of 40˜99.9 wt % of Cu and 0.1˜60 wt % of Zn.

7. The semiconductor package as set forth in claim 1, wherein the core layer comprises CuCo, a composition of the CuCo consisting of 0.1˜99.9 wt % of Cu and 0.1˜99.9 wt % of Co.

8. The semiconductor package as set forth in claim 1, wherein the core layer comprises CuNi, a composition of the CuNi consisting of 0.1˜99.9 wt % of Cu and 0.1˜99.9 wt % of Ni.

9. The semiconductor package as set forth in claim 3, wherein the copper alloy is CuZn, CuCo, CuNi or a combination thereof.

10. The semiconductor package as set forth in claim 3, wherein the second layer comprises CuZn, a composition of the CuZn consisting of 0.1˜99.9 wt % of Cu and 0.1˜99.9 wt % of Zn.

11. The semiconductor package as set forth in claim 3, wherein the second layer comprises CuCo, a composition of the CuCo consisting of 0.1˜99.9 wt % of Cu and 0.1˜99.9 wt % of Co.

12. The semiconductor package as set forth in claim 3, wherein the second layer comprises CuNi, a composition of the CuNi consisting of 0.1˜99.9 wt % of Cu and 0.1˜99.9 wt % of Ni.

13. The semiconductor package as set forth in claim 1, wherein, when the core layer comprises aluminum or an aluminum alloy, the bump ball further comprises an intermediate layer containing nickel between the core layer and the shell layer.

14. The semiconductor package as set forth in claim 1, wherein the aluminum alloy is AlCu, AlZn, AlSi, AlMn, AlMg or a combination thereof.
